(19) United States
(12) Patent Application Publication
(10) Pub. No.: US 2009/0140298 A1
(43) Pub. Date: Jun. 4, 2009

(54) SEMICONDUCTOR DEVICE AND METHOD FOR MANUFACTURING THE DEVICE

(76) Inventor: Jung-Kyu Kim, Anyang-si (KR)

Correspondence Address: SHERR & VAUGHN, PLLC, 620 HERNDON PARKWAY, SUITE 200, HERNDON, VA, 20170, US

(21) Appl. No.: 12/325,733

(22) Filed: Dec. 1, 2008

(30) Foreign Application Priority Data
Dec. 1, 2007 (KR) 10-2007-0124055

(51) Int. Cl. H01L 29/66; H01L 21/00

(52) U.S. Cl. 257/208; 257/202; 438/128; 257/E29.166; 257/E21.001

(57) ABSTRACT

Embodiments relate to a layout structure of a dual port SRAM and a method for forming a SRAM. According to embodiments, a structure where a plurality lines and vias are electrically connected may include first lines that may be electrically connected to a cell region of a memory cell, and a first via, a second line, a second via, a third line, a third via, and a fourth line on and/or over an upper side of the first line,. According to embodiments, the fourth lines arranged on the upper side of the cell region may be formed in a substantially straight form parallel with each other. According to embodiments, the fourth lines may be formed and positioned to prevent bit lines positioned in a cell region of the dual port SRAM from becoming electrically connected to each other.

The present application claims priority under 35 U.S.C. 119 to Korean Patent Application No. 10-2007-0124055 (filed on Dec. 1, 2007), which is hereby incorporated by reference in its entirety.

### BACKGROUND

There may a need for a highly integrated and large capacity semiconductor device. A faster semiconductor device having stable and smooth operation may also be important. Certain technologies, such as micro-machined technology, micro device technology, and circuit design technology may benefit from such a semiconductor, such that technology of semiconductor memory cells, such as Dynamic Random Access Memory (DRAM) or Static Random Access Memory (SRAM) may be improved. For example, in a field of Static Random Access Memory (SRAM), a dual port SRAM, which may perform read and write operations faster than a single port SRAM, may be beneficial. A single port SRAM may include one unit memory cell that may include six transistors. It may use two load transistors, two driving transistors, and two active transistors, which may sequentially perform read and write operations. A dual port SRAM may add two active transistors to a single port SRAM, and may perform a read and write operation in a dual mode. Accordingly, it may be used for an ultra high-speed memory device.

FIG. 1 is a drawing illustrating a third line, a third via, and a fourth line in a dual port SRAM. FIG. 2 is a drawing illustrating the third line and the third via in a unit cell region of a dual port SRAM. FIG. 3 is a drawing illustrating the third via and the fourth line of a dual port SRAM.

Referring to FIGS. 1 to 3, a SRAM may include a plurality of unit memory cells 1. Each unit memory cell 1 may have transistors formed in an active region. Insulating layers, vias, and lines may be sequentially formed on and/or over the transistors. FIGS. 1-3 illustrate third line 31 and third via 41 that may be electrically connected to third line 31 and may be formed on and/or over an upper side of third line 31. Fourth line 51 that may be electrically connected to third via 41 may be formed on and/or over an upper side of third via 41.

FIG. 3 illustrates third via 41 and fourth line 51, which may be formed on and/or over an upper side of third via 41. A portion of fourth line 51, in which third via 41 may be formed, may be protruded. Width W1 of line region 32 outside cell region 10 may be formed to be approximately 0.28 μm. Interval W2 between line region 32 outside cell region 10 and third line 31 inside cell region 10 may be formed to be approximately 0.32 μm. Thus, bit lines 61 and 62, which may be positioned at an upper side of cell region 10 in unit memory cell 1 may protrude in a direction facing each other. Since an interval between bit lines 61 and 62 in the mutually protruded portion may be narrow, there may be a problem in that bit lines 61 and 62 may be electrically connected to each other when depositing copper and performing a CMP process to form fourth line 51. Therefore, a dual port SRAM may be short-circuited and/or the dual port SRAM may not operate. This may reduce a production yield of a SRAM.

### SUMMARY

Embodiments relate to a semiconductor device and a method for manufacturing a semiconductor device. Embodiments relate to a layout structure of a dual port Static Random Access Memory (SRAM) and a method for forming the same.

Embodiments relate to a layout structure of a dual port SRAM and a method for forming the structure, which may prevent a problem that bit lines, which may be positioned in a cell region of a dual port SRAM, may become electrically connected to each other.

According to embodiments, a layout structure of a dual port SRAM where a plurality of lines and vias may be electrically connected may include at least one of the following. First lines that are electrically connected in a cell region of a memory cell. A first via, a second line, a second via, a third line, a third via, and a fourth line that may be sequentially stacked on and/or over an upper side of the first line, where the fourth lines arranged on and/or over the upper side of the cell region may be formed in a straight form parallel with each other.

According to embodiments, a method for manufacturing a layout structure of a dual port SRAM where a plurality of lines and vias may be electrically connected may include at least one of the following. Forming first lines that may be electrically connected to each other in a cell region of a memory cell. Forming a first via, a second line, a second via, a third line, a third via, and a fourth line that may be sequentially stacked on and/or over an upper side of the first line, where the fourth lines arranged on and/or over the upper side of the cell region may be formed in a straight form parallel with each other.

### DRAWINGS

FIG. 1 is a drawing illustrating a third line, a third via, and a fourth line of a dual port SRAM.

FIG. 2 is a drawing illustrating a third line and a third via in a unit cell region of a dual port SRAM.

FIG. 3 is a drawing illustrating a third via and a fourth line of a dual port SRAM.

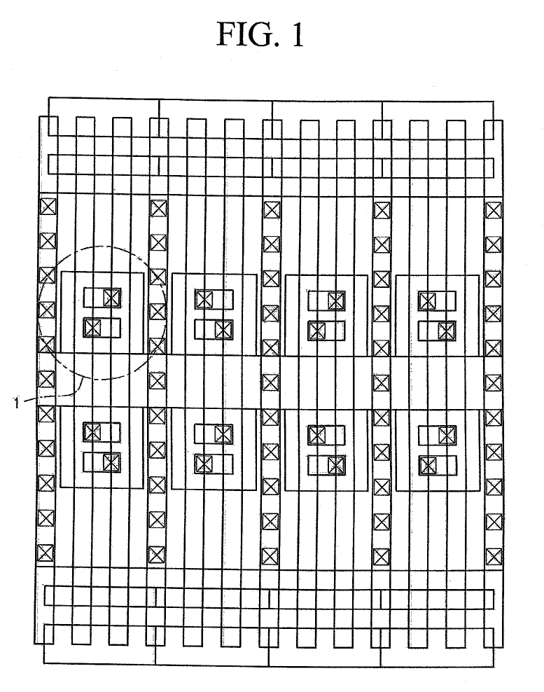

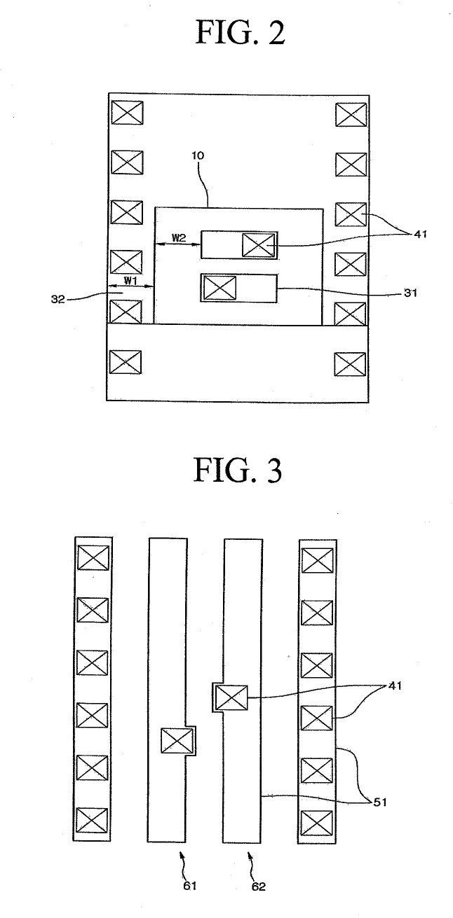

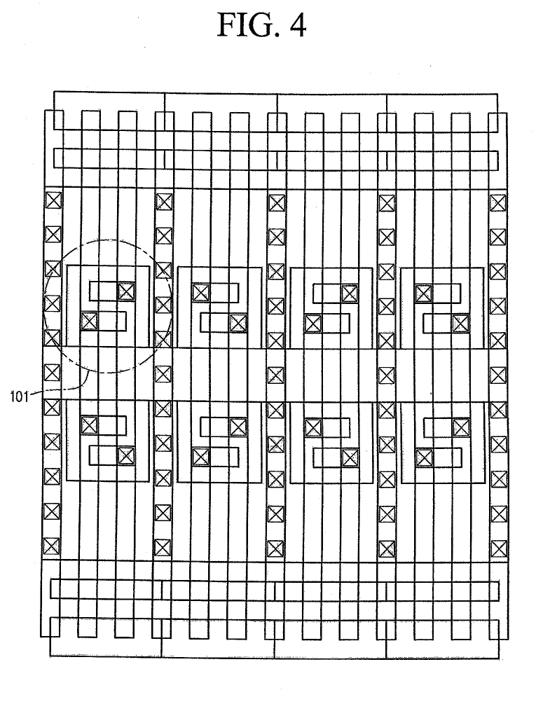

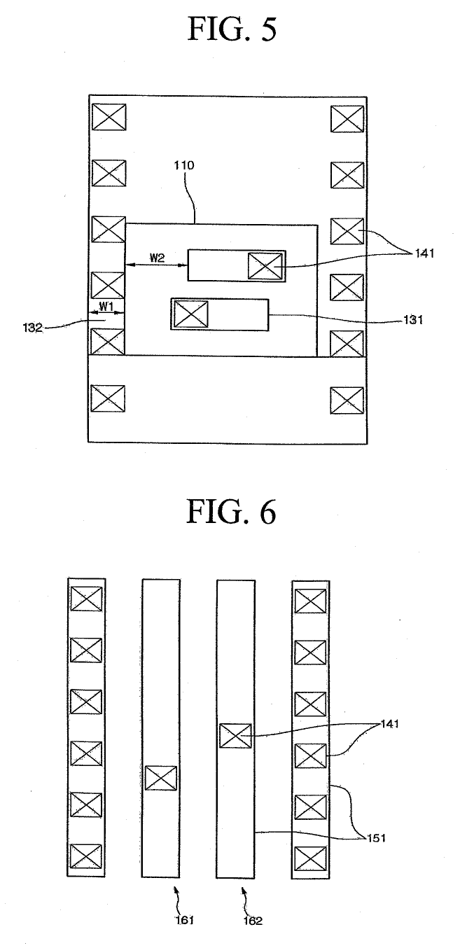

Example FIG. 4 is a drawing illustrating a third line, a third via, and a fourth line of a dual port SRAM according to embodiments.

Example FIG. 5 is a drawing illustrating a third line and a third via in a unit cell region of a dual port SRAM according to embodiments.

Example FIG. 6 is a drawing illustrating a third via and a fourth line of a dual port SRAM according to embodiments.

### DESCRIPTION

Example FIG. 4 is a drawing illustrating a third line, a third via, and a fourth line of a dual port SRAM according to embodiments. Example FIG. 5 is a drawing illustrating a third line and a third via in a unit cell region of a dual port SRAM according to embodiments. Example FIG. 6 is a drawing illustrating a third via and a fourth line of a dual port SRAM according to embodiments.

Referring to example FIGS. 4-6, a SRAM may include a plurality of unit memory cells 101. Each unit memory cell 101 may have transistors formed in an active region. Insulating layers, vias, and lines may be sequentially formed on and/or over the transistors. The vias and lines may be formed in a stack order of a first line a first via, a second line, a second via, third line 131, third via 141, and fourth line 151.

According to embodiments, a structure of third line 131, third via 141, and fourth line 151 may be modified. Third line 131 may be electrically connected to a second via. Third via 141 may be formed on and/or over an upper side of third line 131. Fourth line 151 may be formed on and/or over an upper side of third via 141. To prevent a portion of fourth line 151 from protruding, interval W2 may be expanded. Interval W2 may be between third line 131 and third line region 132, which may be positioned inside a cell region 110, to third line region 132 that may be positioned outside cell region 110. Width W1 of third line region 132 may be reduced and interval W2 between third line region 132 and third line 131 may be increased. A width of fourth line 151 may be reduced and an interval between fourth lines 151 may be increased.

A position of third via 141, which may connect between fourth line 151 and third line 131 may be adjusted. This may make it possible to form fourth lines 151 in a straight form. Width W1 of third line region 132, which may be arranged outside cell region 110, may be formed to be approximately 0.19-0.21 μm. Interval W2 between third line region 132 and third line 131, which may be arranged inside cell region 110, may be formed to be approximately 0.31-0.33 μm. Width W1 of third line region 132 may be reduced and interval W2 between third line region 132 and third line 131 may be increased. According to embodiments, a position of third via 141, which may be positioned on and/or over an upper side of third line 131, may be moved as well as fourth line 151, which may be positioned on and/or over an upper side of third via 141, maybe formed in a straight form. Any one of bit lines 161 and 162 positioned on and/or over an upper side of cell region 110 of unit memory cell 101 may be a bit line and another may be a complementary bit line. Bit lines 161 and 162 may be formed in a substantially straight form, unlike the related art. A width of fourth line 151, including the bit lines 161 and 162, may be formed to be approximately 0.19-0.21 μm. According to embodiments, an interval between fourth lines 151 may be formed to be approximately 0.31-0.33 μm.

A method to form a layout structure of a dual port SRAM according to embodiments will be described with reference to the accompanying drawings. According to embodiments, a method for forming a layout structure of a dual port SRAM according to embodiments may form a layout structure of a dual port SRAM illustrated in example FIGS. 4-6 where a plurality of lines and vias may be electrically connected.

According to embodiments, a first line, which may be electrically connected to a cell region of memory cell 101, may be formed. First via may be formed on and/or over an upper side of the first line, a second line may be formed on and/or over an upper side of the first via. Second via may be formed on and/or over an upper side of the second line. Third line 131 may be formed on and/or over an upper side of the second via. Third via 141 may be formed on and/or over third line 131. Fourth line 151 may be formed on and/or over an upper side of third via 141. According to embodiments, the first via, the second line, the second via, third line 131, third via 141, and fourth line 151 maybe sequentially stacked on and/or over an upper side of the first line.

Referring to example FIG. 6, at least two fourth lines 151 may be arranged on and/or over an upper side of cell region 110 and may be formed in a substantially straight form parallel with each other. This may be achieved by expanding interval W2 between third line 131 and third line region 132, which may be arranged inside cell region 110, into third line region 132 arranged outside cell region 110. According to embodiments, fourth lines 151 may be formed to have a width of approximately 0.19-0.21 μm. According to embodiments, fourth lines 151 may be formed to be spaced from each other at an interval of approximately 0.31-0.33 μm. Fourth lines 151 may also be formed as a bit line and a complementary bit line. According to embodiments, a problem that bit lines 61 and 62 may be electrically connected to each other during depositing copper and performing a CMP process when forming fourth lines 151 may not occur.

A layout structure of a dual port SRAM and a method for forming the structure may prevent a problem that bit lines positioned in a cell region of a dual port SRAM may become electrically connected to each other. According to embodiments, production yield of a SRAM may increase by reducing an occurrence of a short-circuit of a dual port SRAM. According to embodiments, a problem of non-operation of a dual port SRAM may be solved.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a plurality of first lines electrically connected in a cell region of a memory cell; and
a first via, a second line, a second via, a third line, a third via, and at least two fourth lines sequentially stacked over at least one of the plurality of first lines,
wherein the at least two fourth lines are formed over an upper portion of the cell region and are formed in a substantially straight form and parallel with each other.

2. The device of claim 1, wherein an interval between the third line positioned inside the cell region and a third line region extends to a position outside the cell region.

3. The device of claim 2, wherein the interval between the third line and the third line region outside the cell region is in a range between approximately 0.31-0.33 μm.

4. The device of claim 3, wherein a width of the third line region outside the cell region is in a range between approximately 0.19-0.21 μm.

5. The device of claim 1, wherein a width of each of the at least two fourth lines is in a range between approximately 0.19-0.21 μm.

6. The device of claim 5, wherein an interval between each of the at least two fourth lines is in a range between approximately 0.31-0.33 μm.

7. The device of claim 1, wherein an interval between each of the at least two fourth lines is in a range between approximately 0.31-0.33 μm.

8. The device of claim 1, wherein the at least two fourth lines comprise a bit line and a complementary bit line.

9. The device of claim 1, wherein each of the at least two fourth lines is formed to have substantially no protrusions.

10. A device comprising:
at least two first lines formed over a cell region of a memory cell; and
at least two first vias and at least two second lines formed over the at least two first lines,
wherein each of the at least two second lines is formed over respective ones of the at least two first vias, and wherein each of the at least two second lines has a width of approximately 0.19-0.21 μm, and wherein an interval between each of the at least two second lines is approximately 0.31-0.33 μm.

11. The device of claim 10, wherein each of the at least two second lines comprises one of a bit line and a complementary bit line, and is formed in a substantially straight form with substantially no protrusions and substantially parallel with each other.

12. A method comprising:
forming a plurality of first lines electrically connected to each other in a cell region of a memory cell; and then
forming a first via, a second line, a second via, a third line, a third via, and at least two fourth lines that are sequentially stacked over an upper portion of at least one of the plurality of first lines,
wherein the at least two fourth lines are formed over an upper side of the cell region and are formed in a substantially straight form parallel with each other.

13. The method of claim 12, wherein an interval between the third line formed inside the cell region and a third line region extends to a position outside the cell region.

14. The method of claim 13, wherein the interval between the third line and the third line region outside the cell region is in a range between approximately 0.31-0.33 μm.

15. The method of claim 14, wherein a width of the third line region outside the cell region is in a range between approximately 0.19-0.21 μm.

16. The method of claim 12, wherein each of the at least two fourth lines are formed to a width of in a range between approximately 0.19-0.21 μm.

17. The method of claim 16, wherein each of the at least two the fourth lines are formed to have a space between them of in a range between approximately 0.31-0.33 μm.

18. The method of claim 12, wherein an interval between each of the at least two fourth lines is formed to be in a range between approximately 0.31-0.33 μm.

19. The method of claim 12, wherein the at least two fourth lines comprise a bit line and a complementary bit line, respectively.

20. The method of claim 12, wherein each of the at least two fourth lines is formed to have substantially no protrusions.
